(19) United States
(12) Patent Application Publication
(10) Pub. No.: US 2006/0227503 A1
(43) Pub. Date: Oct. 12, 2006

(54) Keyboard module heat dissipation film

(76) Inventors: Su-O Ho, Tao Yuan Shien (TW); I-Hao Chen, Taipei (TW); Shun-Yung Liao, Tao Yuan Shien (TW); Kun-Ho Lee, Taipei (TW)

Correspondence Address: RABIN & BERDO, P.C., Suite 500, 1101 14 Street, N.W., Washington, DC, 20005, US

(21) Appl. No.: 11/198,157

(22) Filed: Aug. 8, 2005

(30) Foreign Application Priority Data
Apr. 9, 2005 (TW) 94206119

(51) Int. Cl. G06F 1/20; H05K 5/00

(52) U.S. Cl. 361/687; 361/680; 361/683; 361/688

(57) ABSTRACT

A keyboard module heat dissipation film is described. The keyboard module heat dissipation film is utilized in a notebook computer and can endure a working temperature of interior components in the notebook computer. The film is made of a water repellent material and includes a plurality of needle apertures to allow the cooling air passing therethrough. Dropped water can form sweat on the surface of the film due to the water repellent property of the film so as to prevent from dropping into the notebook computer.

### RELATED APPLICATIONS

The present application is based on, and claims priority from, Taiwan Application Serial Number 94206119, filed Apr. 19, 2005, the disclosure of which is hereby incorporated by reference herein in its entirety.

### BACKGROUND OF THE INVENTION

1. Field of Invention

The invention relates to a keyboard module heat dissipation film and, in particular, to a keyboard module heat dissipation film that is water repellent, air ventilating, and heat resistant.

2. Related Art

A usual method of testing whether a notebook computer is water droplet repellent is to first pour about 30 cc of liquid into the center of its keyboard. One then makes the notebook computer stand on its side and wipes it. The notebook computer is left like that and restarted after 24 hours. It passes the water droplet repellent test if it can function normally.

To pass the water repellent test, the bottom of the keyboard module of a conventional notebook computer is usually tightly attached with an aluminum foil or plastic film. However, even though the aluminum foil or the plastic film prevents water from dropping through, it also blocks the airflow. The heat produced inside the notebook computer can be taken away only by the predetermined cooling airflow field. If the notebook computer is further minimized in its interior space, the cooling airflow field will be sacrificed in order to accommodate devices. This will result in bad cooling efficiency and shortens the lifetime of the notebook computer.

### SUMMARY OF THE INVENTION

An object of the invention is to provide a heat dissipation film. After pouring some liquid on the keyboard of a computer and letting it stand on its side, the liquid does not permeates into the notebook computer.

Another object of the invention is to provide a heat dissipation film to improve the cooling airflow inside the notebook computer. The heat produced inside the notebook computer can thus be taken away.

To achieve the above objects, the disclosed heat dissipation film is provided between a keyboard module of a notebook computer and its interior components. The heat dissipation film is a film made of a water repellent material that can endure a working temperature of the interior components. There are a plurality of needle apertures on the film.

The heat dissipation film is a melt-blown nonwoven fabric of density 35 g/mm² and made of such water repellent materials as PE and PP. The needle apertures are in the specification of 200 meshes. The heat dissipation film is attached to the keyboard module or fixed on the keyboard film or notebook computer by a fixing device.

### BRIEF DESCRIPTION OF THE DRAWINGS

These and other features, aspects and advantages of the invention will become apparent by reference to the following description and accompanying drawings which are given by way of illustration only, and thus are not limitative of the invention, and wherein:

FIG. 1 is a schematic view showing the application of the disclosed heat dissipation film.

### DETAILED DESCRIPTION OF THE PREFERRED EMBODIMENT

The present invention will be apparent from the following detailed description, which proceeds with reference to the accompanying drawings, wherein the same references relate to the same elements.

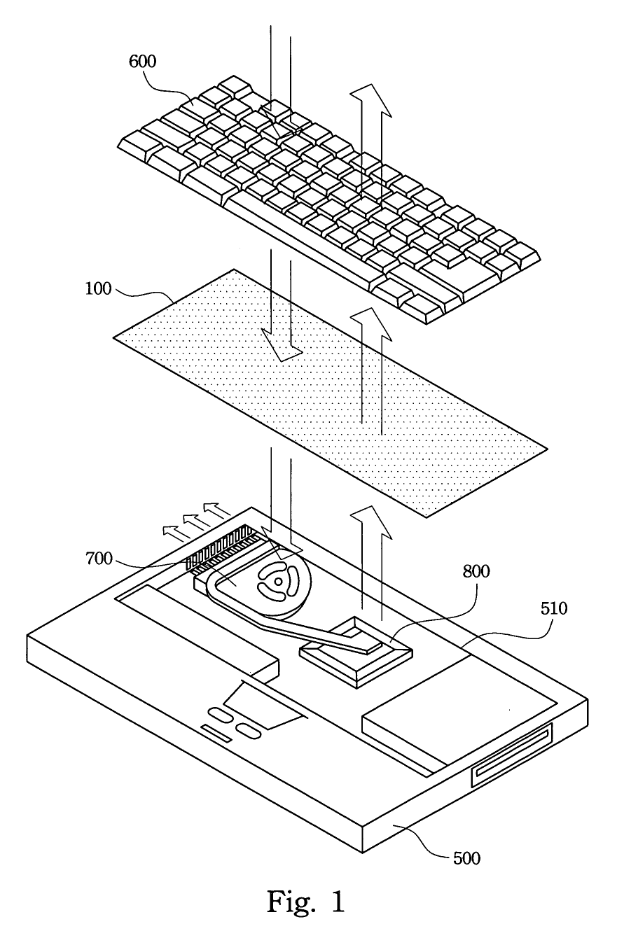

As shown in FIG. 1, the keyboard module 600 is provided at a predetermined opening 510 on the notebook computer 500. After decomposing the keyboard module 600 from the notebook computer 500, one can see the interior components 800 of the notebook computer. The disclosed heat dissipation film 100 is provided between the keyboard module 600 and the interior components 800. The heat dissipation film 100 is tightly attached to the back of the keyboard module 600, or is fixed on the back of the keyboard module 600 or the opening 510 using a fixing device (note shown). The heat dissipation film 100 is a film made of a water repellent material and contains needle apertures, so that the heat dissipation film 100 is both water repellent and air ventilating. That is, the cooling air can flow through the heat dissipation film 100 via the needle apertures. Once a liquid is dropped on the heat dissipation film 100, they form sweat due to the water repellent property of the film so as to prevent from dropping into the notebook computer. This helps passing the water repellent test. Moreover, to minimize the volume of the notebook computer, it is preferable to have a thinner heat dissipation film 100. Since the components 800 generate a high temperature when they are working, it is thus preferable for the heat dissipation film 100 to withstand such a high temperature environment.

The arrows in FIG. 1 indicate the direction of the cooling airflow. The cooling air is sucked by the fan of the heat-dissipating device 700 into the notebook computer 500 via the heat dissipating film 100. The heat generated by the components 800 is directly brought outside the notebook computer by the heated cooling air via the heat dissipation film 100. In addition to the originally designed cooling airflow field, the disclosed heat dissipation film 100 provides extra airflow to improve the cooling efficiency. When designing smaller notebook computers, one may use the disclosed heat dissipation film 100 to arrange the cooling airflow field, making the space usage inside the notebook computer more flexible.

To be water repellent, air ventilating, and heat resistant, the disclosed heat dissipation film 100 may be a melt-blown nonwoven fabric made of a water repellent material such as PE and PP. The density of the melt-blown nonwoven fabric is preferably 35 g/mm². However, melt-blown nonwoven fabrics of other specifications are also allowed. In order to prevent the liquid from permeating through the needle apertures while keeping the cooling airflow, the needle aperture density is preferably the specification of 200 meshes. As long as the liquid can be prevented from permeating through and the airflow is not blocked, needle apertures in other specifications are also allowed.

From the above embodiment, we see that the invention has the following advantages:

1. If one pours a liquid on the keyboard and immediately stands the notebook computer on its side, the liquid does not permeate into the machine.

2. The cooling airflow field inside the notebook computer is improved to bring away the heat more efficiently.

3. The interior space of the notebook computer is more flexible so that notebook computers of smaller volumes are possible.

While the invention has been described by way of example and in terms of the preferred embodiment of a notebook computer, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A keyboard module heat dissipation film inside a notebook computer and fixed on a keyboard module, the heat dissipation film being a film made of a water repellent material that endures a working temperature of interior components in the notebook computer and comprises a plurality of needle apertures.

2. The keyboard module heat dissipation film of claim 1, wherein the water repellent material includes PE and PP.

3. The keyboard module heat dissipation film of claim 1 comprising a melt-blown nonwoven fabric.

4. The keyboard module heat dissipation film of claim 3, wherein the melt-blown nonwoven fabric has a density of 35 g/mm².

5. The keyboard module heat dissipation film of claim 1, wherein the density of the needle apertures includes the specification of 200 meshes.

6. The keyboard module heat dissipation film of claim 1 attached to the keyboard module.

7. The keyboard module heat dissipation film of claim 1 fixed on the keyboard module using a fixing device.

8. The keyboard module heat dissipation film of claim 1 fixed on the notebook using a fixing device.

9. The keyboard module heat dissipation film of claim 1 fixed between the keyboard module and the interior components.

10. A keyboard module with a heat dissipation film for a notebook computer, the notebook computer including a plurality of interior components, and the heat dissipation film being made of a water repellent material that endures a working temperature of the interior components in the notebook computer and comprises a plurality of needle apertures.

11. The keyboard module of claim 1, wherein the water repellent material includes PE and PP.

12. The keyboard module of claim 1 comprising a melt-blown nonwoven fabric.

13. The keyboard module of claim 12, wherein the melt-blown nonwoven fabric has a density of 35 g/mm².

14. The keyboard module of claim 1, wherein the density of the needle apertures includes the specification of 200 meshes.

15. The keyboard module of claim 1, wherein the heat dissipation film is fixed on the back and attached to the keyboard module.

16. The keyboard module of claim 15, wherein the heat dissipation film is fixed on the keyboard module using a fixing device.

17. The keyboard module of claim 1, wherein the heat dissipation film is fixed inside the notebook using a fixing device.

18. The keyboard module of claim 1, wherein the heat dissipation film is fixed between the keyboard module and the interior components.
